(19) United States
(12) Patent Application Publication
(10) Pub. No.: US 2007/0272827 A1
(43) Pub. Date: Nov. 29, 2007

(54) Image sensor package having mount holder attached to image sensor die

(75) Inventors: Byong II Heo, Kwangju-si (KR); Won Geol Lee, Kwangju-si (KR); Kyong Jun Kim, Kwangju-si (KR)

Correspondence Address: GUNNISON MCKAY & HODGSON, LLP;GARDEN WEST OFFICE PLAZA, SUITE 220, 1900 GARDEN ROAD, MONTEREY, CA, 93940, US

(73) Assignee: Amkor Technology, Inc.

(21) Appl. No.: 11/116,631

(22) Filed: Apr. 27, 2005

(51) Int. Cl. H01L 27/00; H01J 5/02; H01J 40/14

(52) U.S. Cl. 250/208.1; 250/239

(57) ABSTRACT

An image sensor package and a method for manufacturing the same are disclosed. For example, a mount holder is directly attached on an image sensor die, not a substrate. Here, on the mount holder, a lens or a barrel having lens are attached. Also, the mount holder is interlocked by an encapsulant, so that it is not easily separated from the image sensor. Accordingly, the width of the mount holder can be smaller than that of the image sensor die, so that the entire width of the image sensor package becomes smaller. Moreover, the electrically conductive wire is located at the outside of the mount holder and is perfectly surrounded by the encapsulant, thereby preventing the oxidization of the wire.

### BACKGROUND OF THE INVENTION

1. Field of the Invention

The present invention relates to an image sensor package and its manufacturing method.

2. Description of the Related Art

Generally, an image sensor serves to sense subject information and convert them into image signals. Also, the image sensor can mainly divide into a camera tube and a solid image sensor. The former is a vidicon, a plumbicon and so on, and the latter is a Complementary Metal Oxide Semiconductor (CMOS), a Charge Coupled Device (CCD) and so forth. Among them, in the solid image sensor, a barrel having lens is coupled to the CMOS image sensor die or the CCD image sensor die.

For example, the conventional image sensor package comprises a substrate, an image sensor die attached on the substrate, an electrically conductive wire for electrically connecting the substrate to the image sensor die, a mount holder attached on the outside of the image sensor die and the wire, and a barrel coupled to the mount holder.

Here, the external images transmit to the lens of the barrel and then, they convert into electrical signals through the image sensor die. Thereafter, the electrical signals transmit to the external device through the wire and the substrate.

However, in the conventional image sensor package, since the image sensor die is exposed to an external atmosphere during sawing, die attaching and wire bonding operations, there is a problem in that the optical efficiency is remarkably lowered. That is, the image sensor dies are separated from the wafer into individual pieces in the sawing process using a diamond blade and so on. At this time, the image sensor dies are contaminated by many particles generated from the sawing process, so that its optical efficiency is lowered. Also, in the die attaching and wire bonding processes, the image sensor die is attached on the substrate while being exposed to outside, so that the image sensor dies are contaminated by many particles, thereby lowering the optical efficiency thereof.

Also, in the conventional image sensor package, since the mount holder and the barrel are attached on the substrate at the peripheral of the image sensor die, there is a problem in that the entire width of the package becomes larger. That is, the width of the secondary mount holder and barrel is actually larger than that of the image sensor die for dealing with the external images, so that the width of the package becomes larger needlessly.

Moreover, in the conventional image sensor package, the wire is not encapsulated by the encapsulant and is exposed to outside, so that it is easily contaminated and oxidized, thereby lowering the reliance of the package.

### BRIEF SUMMARY OF THE INVENTION

In accordance with various embodiments, an image sensor package and a method for manufacturing the same are disclosed. For example, a mount holder is directly attached on an image sensor die, not a substrate. Here, on the mount holder, a lens or a barrel having lens are attached. Also, the mount holder is interlocked by an encapsulant, so that it is not easily separated from the image sensor. Accordingly, the width of the mount holder can be smaller than that of the image sensor die, so that the entire width of the image sensor package becomes smaller. Moreover, the electrically conductive wire is located at the outside of the mount holder and is perfectly surrounded by the encapsulant, thereby preventing the oxidization of the wire.

The present invention will be more apparent from the following detailed description taken in conjunction with the accompanying drawings.

### BRIEF DESCRIPTION OF THE DRAWINGS

FIG. 1 is a sectional view of an image sensor package according to one embodiment of the present invention;

FIG. 2 is a sectional view of an image sensor package according to another embodiment of the present invention;

FIG. 3 is a sectional view of an image sensor package according to further another embodiment of the present invention;

FIG. 4 is a sectional view of an image sensor package according to further another embodiment of the present invention;

FIG. 5 is a sectional view showing a wafer providing operation among a method for manufacturing an image sensor package according to the present invention;

FIG. 6A through FIG. 6C are sectional views showing a mount holder attaching operation among a method for manufacturing an image sensor package according to the present invention;

FIG. 7 is a sectional view showing a die sawing operation, in which the image sensor dies are separated from the wafer into individual pieces, among a method for manufacturing an image sensor package according to the present invention;

FIG. 8 is a sectional view showing a die attaching operation, in which the image sensor die is attached on the substrate, among a method for manufacturing an image sensor package according to the present invention;

FIG. 9 is a sectional view showing a wire bonding operation, in which the image sensor die is wire-bonded on the substrate, among a method for manufacturing an image sensor package according to the present invention;

FIG. 10A to FIG. 10B are sectional views showing an encapsulation operation among a method for manufacturing an image sensor package according to the present invention; and

FIG. 11 is a sectional view showing a singulation operation among a method for manufacturing an image sensor package according to the present invention.

Common reference numerals are used throughout the drawings and the detailed description to indicate the same elements.

### DETAILED DESCRIPTION OF THE INVENTION

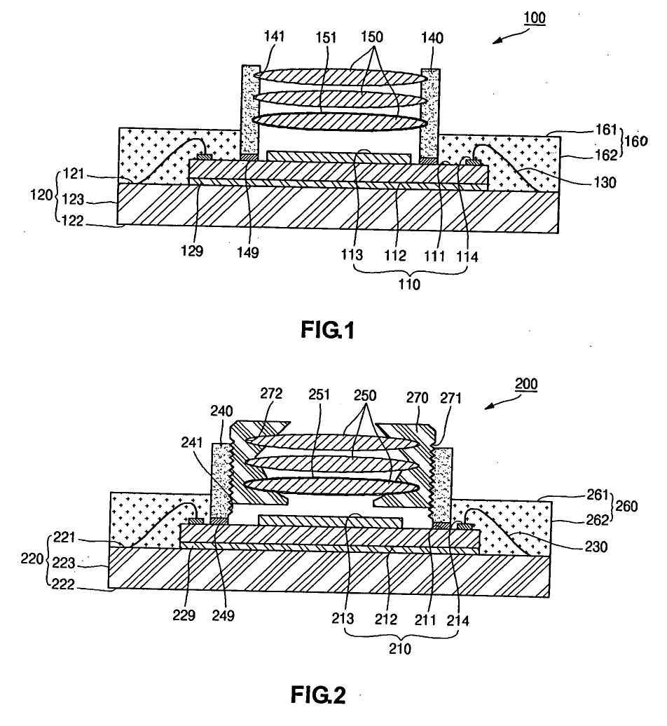

Referring to FIG. 1, a sectional view of an image sensor package 100 according to one embodiment of the present invention is illustrated.

As shown in FIG. 1, the image sensor package 100 according to one embodiment of the present invention includes an image sensor die 110 for sensing external images and converting them into electrical signals, a substrate 120 attached to the image sensor die 110, a plurality of conductive wires 130 for electrically connecting the image sensor die 110 to the substrate 120, a mount holder 140 directly attached on the image sensor die 110, a plurality of lens 150 located inside the mount holder 140, and an encapsulant 160 for encapsulating the image sensor die 110 located on the outside of the mount holder 140 and the lens 150, the substrate 120, and the conductive wires 130.

Firstly, the image sensor die 110 includes an approximately planar first surface 111 and an approximately planar second surface 112 opposed to the first surface 111. Also, the image sensor die 110 includes an image sensing region 113 for sensing the exterior images and converting them into predetermined electrical signals at an approximately center of the first surface 111 and at least one bond pad 114 outwardly separated from the image sensing region 113 at a predetermined distance. In other words, the bond pad 114 is mainly formed at the inside of the edge of the first surface 111. The image sensor die 110 can be applied to the CMOS manner or the CCD manner all together.

The substrate 120 includes an approximately planar first surface 121 and an approximately planar second surface 122 opposed to the first surface 121. Also, the glass substrate 120 includes a third surface 123 approximately perpendicular to the first and second surfaces 121 and 122 at a common end (an edge) thereof. Moreover, the first surface 121 of the substrate 120 is bonded to the second surface 112 of the image sensor die 110 at an approximately central portion of the first surface 121 of the substrate 120 by means of an adhesive 129. Here, in order to easily bond the image sensor die 110 with the substrate 120, the width of the substrate 120 is larger than that of the image sensor die 110. Also, though the substrate 120 is not concretely shown in FIG. 1, it may be a hard printed circuit board, a soft printed circuit board, a lead frame or its equivalent. However, the present invention is not limited to any kind of the substrate 120. Moreover, electrically conductive patterns or leads and so on can be formed at the surface of the substrate 120 to be connected with the electrically conductive wires 130, though it is not shown in FIG. 1. Furthermore, the adhesive 129 for bonding the image sensor die 110 with the substrate 120 each other may be a conventional epoxy adhesive, a both-sided adhesive tape, a both-sided adhesive film or its equivalent. However, the present invention is not limited to any kind of the adhesive 129.

The bond pads 114 of the image sensor die 110 and the substrate 120 are electrically connected to each other by means of the electrically conductive wires 130. That is, the electrically conductive wire 130 serves to electrically connect the bond pad 114 of the first surface 111 of the image sensor die 110 with the electrically conductive pattern or lead of the substrate 120 each other. Of course, it takes the shape of at least one electrically conductive wire 130 like the bond pad 114. Here, the material of the electrically conductive wire 130 may be Al wire, Au wire, Cu wire or its equivalent. However, the present invention is not limited to any material of the conductive wire.

The mount holder 140 is attached on the first surface 111 of the image sensor die 110. That is, the mount holder 140 is attached on the first surface 111 of the image sensor die 110 between the outside of the image sensing region 113 and the bond pad 114. Here, the width of the mount holder 140 is smaller than that of the image sensor die 110, so that the entire width of the image sensor package 100 becomes smaller. The shape of the mount holder 140 may be an approximately hollow circular cylinder, so as to transmit the external images to the image sensing region 113. Also, the mount holder 140 may be various shapes, such as a rectangular shape or a pentagonal shape and so forth. However, the present invention is not limited to any shape of the mount holder 140. Moreover, a recess 141 of a predetermined depth is formed inside the mount holder 140, in order that the following lens 150 is coupled to and not separated from the mount holder 140. Furthermore, the mount holder 140 is attached on the first surface 111 of the image sensor die 110 by means of an adhesive 149. The adhesive 149 also, may be a conventional epoxy adhesive, a both-sided adhesive tape, a both-sided adhesive film or its equivalent, as described above. However, the present invention is not limited to any kind of the adhesive 149. Here, the mount holder 140 may be a thermoplastic resin, a thermosetting resin, a ceramic or its equivalent. However, the present invention is not limited to any material of the mount holder 140.

At least one lens 150 is coupled to the inside of the mount holder 140 and properly adjusts the focus of the external images, so that the maximum light reaches the image sensing region 113. Also, an infrared ray protection coating layer 151 can be formed at the surface of at least one lens 150, in order that the visibility of the image is not lowered on account of the infrared rays. Here, in the case of the image sensor package for an exclusively infrared ray imaging system, the infrared ray protection coating layer 151 cannot be formed. Moreover, though three convex lenses 150 are shown in FIG. 1, the present invention is not limited to any number and shape of the lens 150. That is, the number of the lens 150 may be above or below 3 and the shape of the lens 150 may be a mixing shape of convex and concave lens.

Finally, the encapsulant 160 covers the image sensor die 110 located on the outside of the mount holder 140, the substrate 120, and the conductive wires 130. Such an encapsulant 160 allows the image sensor die 110, the substrate 120 and the conductive wires 130 to be protected from external environment such as a mechanical, chemical and electrical impacts and an oxidizing phenomenon and so on. Here, the mount holder 140 is surrounded by the encapsulant 160, so that it prevents the mount holder 140 from being easily separated from the image sensor die 110 on account of the external impact. Also, the encapsulant 160 includes approximately planar first surface 161 and approximately planar second surface 162 approximately perpendicular to the first surface 161 at an end (an edge) thereof. Here, the first surface 161 of the encapsulant 160 is approximately paralleled to the first surface 111 of the image semiconductor die 110 or the first surface 121 of the substrate 120 and is approximately perpendicular to the mount holder 140. Moreover, since the prescribed region of the mount holder 140 is protruded and exposed from the first surface 161 of the encapsulant 160 to the outside at a predetermined length, the lens 150 of the desired number can be properly combined with the mount holder 140.

Furthermore, the second surface 162 of the encapsulant 160 is flushed with the third surface 123 of the substrate 120. However, the present invention is not limited to this structure. The material of the encapsulant 160 may be an epoxy molding compound using a molding manner, an under fill using a dispensing manner or its equivalent. However, the present invention is not limited to any material of the encapsulant 160.

Referring to FIG. 2, a sectional view of an image sensor package 200 according to another embodiment of the present invention is illustrated. Since the image sensor package 200 as shown in FIG. 2 is similar to the image sensor package 100 of FIG. 1, it will be described around those differences existing herein below. First surface 211, second surface 212, image sensing region 213, bond pads 214, substrate 220, first surface 221, second surface 222, third surface 223, adhesive 229, conductive wires 230, adhesive 249, encapsulant 260, first surface 261, and second surface 262 of image sensor package 200 of FIG. 2 are substantially similar to first surface 111, second surface 112, image sensing region 113, bond pads 114, substrate 120, first surface 121, second surface 122, third surface 123, adhesive 129, conductive wires 130, adhesive 149, encapsulant 160, first surface 161, and second surface 162 of image sensor package 100 of FIG. 1, respectively.

As shown in FIG. 2, a plurality of screw threads 241 is formed at the inside diameter surface of a mount holder 240. Also, a barrel 270 is coupled to the screw threads 241. Here, a plurality of screw threads 271 is also formed at the outside diameter surface of the barrel 270, so that the screw threads 241 and 271 of the mount holder 240 and the barrel 270 can be coupled to each other. Moreover, a plurality of recesses 272 is formed inside the barrel 270, in order that a plurality of lens 250 is coupled to the recesses, respectively. Here, an infrared ray protection coating layer 251 can be formed at the surface of at least one lens 250, in order to intercept the infrared rays.

With this image sensor package 200 according to the present invention, the barrel 270 is simply coupled to the mount holder by using the screw coupling manner and is rotated in a predetermined direction, so that the focal distance of the lens 250 can be easily adjusted. That is, in the image sensor package 100 of FIG. 1, since the lens is directly coupled to the mount holder, the location of the mount holder and lens should be accurately controlled, so as to accurately adjust the focal distance of the lens. However, in the image sensor package 200 according to this embodiment of the present invention, since the focal distance of the lens can be easily adjusted by rotating the barrel 270 in a predetermined direction, it is not necessary to minutely adjust the location of the mount holder and lens and so on. Here, in the image sensor package 200, the mount holder is also installed on the image sensor die 210, so that the entire width of the image sensor package 200 becomes smaller.

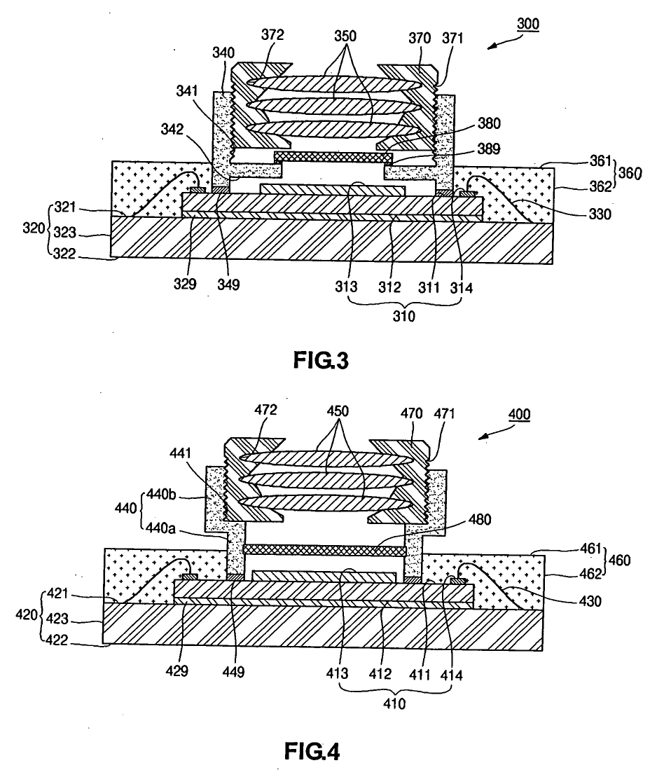

Referring to FIG. 3, a sectional view of an image sensor package 300 according to further another embodiment of the present invention is illustrated. Since the image sensor package 300 as shown in FIG. 3 is similar to the image sensor package 200 of FIG. 2, it will be described around those differences existing herein below. First surface 311, second surface 312, bond pads 314, substrate 320, first surface 321, second surface 322, third surface 323, adhesive 329, conductive wires 330, screw threads 341, adhesive 349, encapsulant 360, first surface 361, second surface 362, screw threads 371, and recess 372 of image sensor package 300 of FIG. 3 are substantially similar to first surface 211, second surface 212, bond pads 214, substrate 220, first surface 221, second surface 222, third surface 223, adhesive 229, conductive wires 230, screw threads 241, adhesive 249, encapsulant 260, first surface 261, second surface 262, screw threads 271, and recess 272 of image sensor package 200 of FIG. 2, respectively.

As shown in FIG. 3, a protrusion 342 is protruded from the inside of a mount holder 340 to the inside at a predetermined length. Also, a separate infrared ray protection glass 380 is bonded to the protrusion 342 by means of an adhesive 389 in order to intercept the infrared rays. Therefore, it is not necessary to form a separate infrared ray protection coating layer at a lens 350 located at the inside of the barrel 370. In the meantime, it is necessary for the protrusion 342 to properly restrict the length thereof, in order to prevent the amount of light reaching an image sensing region 313 from being decreasing. For example, it is preferred that the length of the protrusion 342 is less than the maximum thickness of the barrel 370. Similarly, in the image sensor package 300, the mount holder 340 is also installed on the image sensor die 310, so that the entire width of the image sensor package 300 becomes smaller.

Referring to FIG. 4, a sectional view of an image sensor package 400 according to further another embodiment of the present invention is illustrated. Since the image sensor package 400 as shown in FIG. 4 is similar to the image sensor package 300 of FIG. 3, it will be described around those differences existing herein below. First surface 411, second surface 412, bond pads 414, substrate 420, first surface 421, second surface 422, third surface 423, adhesive 429, conductive wires 430, screw threads 441, adhesive 449, encapsulant 460, first surface 461, second surface 462, screw threads 471 and recess 472 of image sensor package 400 of FIG. 4 are substantially similar to first surface 311, second surface 312, bond pads 314, substrate 320, first surface 321, second surface 322, third surface 323, adhesive 329, conductive wires 330, screw threads 341, adhesive 349, encapsulant 360, first surface 361, second surface 362, screw threads 371 and recess 372 of image sensor package 300 of FIG. 3, respectively.

As shown in FIG. 4, a mount holder 440 can be divided into a first portion 440a and a second portion 440b, which are different in diameter. That is, the mount holder 440 includes the first portion 440a of a predetermined diameter bonded to an image sensor die 440a and the second portion 440b having a diameter larger than that of the first portion 440a thereon. A plurality of screw threads 441 is formed at the inside diameter surface of the second portion 440b. Also, a barrel 470 is coupled to the screw threads 441. Also, an infrared ray protection glass 480 can be bonded to the inside of the first portion 440a of the mount holder 440. Here, instead of the infrared ray protection glass 480, an infrared ray protection coating layer 251 (see FIG. 2) may be formed at the surface of a specific lens 450.

With this image sensor package 400 according to the present invention, since the mount holder 440 includes the first portion 440a and the second portion 440b having a diameter larger than that of the first portion 440a, the mount holder 440 can be attached on the image sensor die 410 and plenty of the external image information can be transmitted to the image sensing region 413. Similarly, in the image sensor package 400, the mount holder 440 is also installed on the image sensor die 410, so that the entire width of the image sensor package 400 becomes smaller.

Hereinafter, a method for manufacturing an image sensor package according to the present invention will be described. Also, it will be described around the image sensor package 300 as shown in FIG. 3 herein below.

Referring to FIG. 5, a wafer providing operation among a method for manufacturing an image sensor package according to the present invention is illustrated.

As shown in FIG. 5, a wafer 310′ having a plurality of image sensor dies 310 is provided. Here, each image sensor die 310 is sawed along scribe lines 315 in a sawing process in future, so that the image sensor dies 310 are separated into individual pieces. Also, each image sensor die 310 includes the image sensing region 313 formed at an approximately center of one surface thereof and a plurality of bond pads 314 formed at the outside of the image sensing region 313. Here, though four image sensor dies 310 are shown in the drawing, many more image sensor dies 310 are actually formed at one wafer 310′.

In FIG. 5, the reference numeral 311 denotes the first surface having the image sensing region 313 and the bond pads 314 and the reference numeral 312 denotes planar the second surface opposed to the first surface 311.

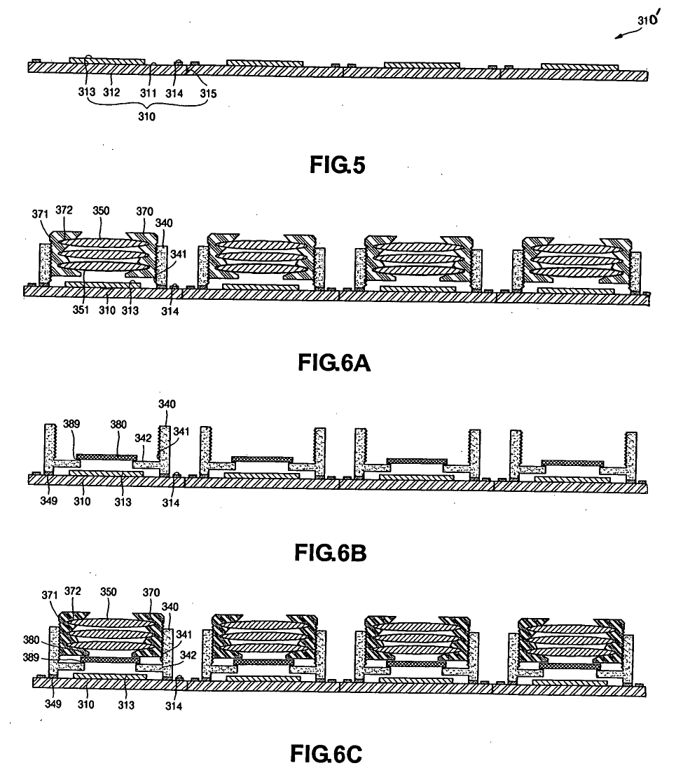

Referring to FIG. 6A through FIG. 6C, a mount holder attaching operation among a method for manufacturing an image sensor package according to the present invention is illustrated.

Firstly, as shown in FIG. 6A, the mount holder 340, which is coupled to the lens 350 and the barrel 370, can be attached on the surface of the image sensor die 310 between the image sensing region 313 and the bond pad 314. Here, the lens 350 is coupled to the recess 372 and the mount holder 340 screws on the barrel 370. That is, a plurality of screw threads 341 and 371 is formed at the inside diameter surface of the mount holder 340 and at the outside diameter surface of the barrel 370. Also, the infrared ray protection coating layer 351 can be formed at the surface of a specific lens among the lens 350, which are coupled to the barrel 370.

On succession, as shown in FIG. 6B, the mount holder 340 having the infrared ray protection glass 380 can be attached on the surface of the image sensor die 310 between the image sensing region 313 and the bond pad 314. Here, next to this operation, the barrel 370 having the lens 350 can be coupled to the mount holder 340. Also, though the protrusion 342 is formed at the inside of a mount holder 340 and the infrared ray protection glass 380 is attached on the protrusion 342 in FIG. 6B, instead of this shape, a recess can be formed at the inside of the mount holder 340 and the infrared ray protection glass can be directly attached to the recess.

Continuously, as shown in FIG. 6C, the mount holder 340 having the lens 350, the barrel 370 and the infrared ray protection glass 380 can be attached on the surface of the image sensor die 310 between the image sensing region 313 and the bond pad 314. Here, the lens 350 is coupled to the recess 372 of the barrel 370 and the infrared ray protection glass 380 can be directly attached to the protrusion 342 of the mount holder 340. Also, though the protrusion 342 is formed at the inside of a mount holder 340 and the infrared ray protection glass 380 is attached on the protrusion 342 in FIG. 6C, instead of this shape, a recess can be formed at the inside of the mount holder 340 and the infrared ray protection glass can be directly attached to the recess.

In the meantime, the mount holder 340 is attached on the image sensor die 310 by means of an adhesive 349. The adhesive 349 also, may be a conventional epoxy adhesive, a both-sided adhesive tape, a both-sided adhesive film or its equivalent, as described above. However, the present invention is not limited to any kind of the adhesive 349. Also, the mount holder 340, which can be directly coupled to the plurality of lens 350 without using the barrel 370, can be attached on the image sensor die 310. In this case, the infrared ray protection coating layer can be formed at the surface of a specific lens among the lens 350.

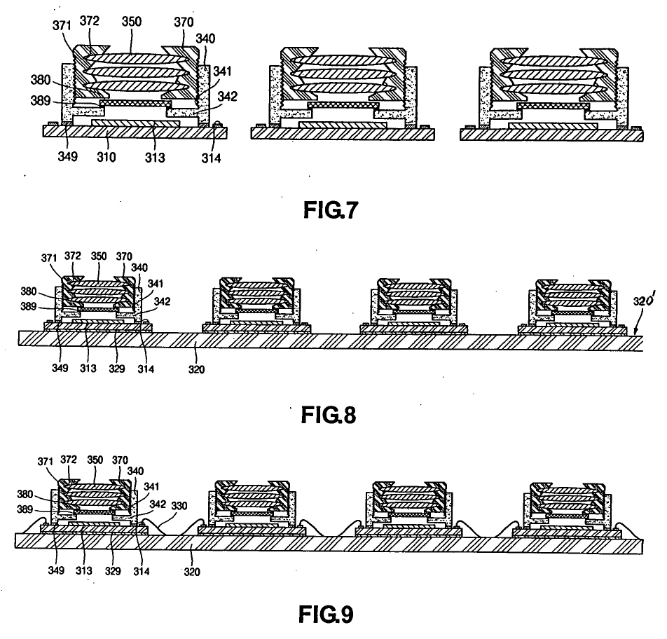

Referring to FIG. 7, a die sawing operation, in which the image sensor dies are separated from the wafer into individual pieces, among a method for manufacturing an image sensor package according to the present invention is illustrated.

As shown in FIG. 7, where the attaching operation of the mount holder 340 is completed on the wafer as describe above, each image sensor die 310 is sawed along scribe lines 315 by means of a diamond blade and the like so that the image sensor dies 310 are separated into individual pieces. At this case, the image sensing region 313 of the image sensor die 310 is already surrounded by the mount holder 340. Accordingly, as though much particle is generated during the sawing process through the diamond blade as described above, the particles are not penetrated into the image sensing region 313. That is, in spite of such a sawing process, the optical efficiency of the image sensing die is not lowered at all. Here, the mount holder can be attached depending on the process conditions (Yield or Productivity), next to the following die attaching process.

By this time, the examples, in which the mount holder 340 having the lens 350, the barrel 370 and the infrared ray protection glass 380 is attached on each image sensor die 310, has been shown in the drawings. Hereinafter, a method for manufacturing an image sensor package according to the present invention will be described around the examples.

Referring to FIG. 8, a die attaching operation, in which the image sensor die is attached on the substrate, among a method for manufacturing an image sensor package according to the present invention is illustrated.

As shown in FIG. 8, the image sensor die 310 is attached on the predetermined region of the substrate 320 by means of an adhesive 329, which is interposed between the surface of the image sensor die 310 opposed to the image sensing region 313 and the substrate 320. Here, the substrate can be of a strip configuration, in order to maximize the yield of the package. That is, in order to manufacture several image sensor package in one strip 320′, a plurality of image sensor dies 310 is bonded on one substrate strip 320′. Also, though the substrate 320 is not concretely shown in FIG. 8, it may be a hard printed circuit board, a soft printed circuit board, a lead frame or its equivalent. However, the present invention is not limited to any kind of the substrate 320. Moreover, an electrically conductive pattern or a lead (not shown) for wire-bonding can be on the surface of the substrate 320. The adhesive 329 for bonding the image sensor die 310 and the substrate 320 also, may be a conventional epoxy adhesive, a both-sided adhesive tape, a both-sided adhesive film or its equivalent, as described above. However, the present invention is not limited to any kind of the adhesive 329.

Referring to FIG. 9, a wire bonding operation, in which the image sensor die is wire-bonded on the substrate, among a method for manufacturing an image sensor package according to the present invention is illustrated.

As shown in FIG. 9, the bond pad 314 of the image sensor die 310, which is located at the outside of the mount holder 340, is electrically connected to the predetermined region of the substrate 320. That is, the bond pad 314 of the image sensor die 310 is electrically connected to the electrically conductive pattern or lead (not shown) of the substrate 120. Here, the material of the electrically conductive wire 330 may be Au wire, Al wire, Ag wire, Cu wire or its equivalent. However, the present invention is not limited to any material of the conductive wire.

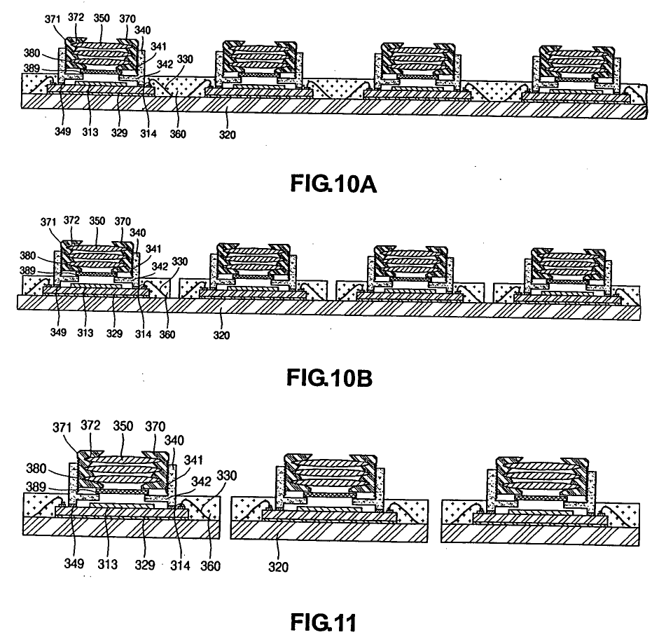

Referring to FIG. 10A to FIG. 10B, an encapsulation operation among a method for manufacturing an image sensor package according to the present invention is illustrated.

Firstly, as shown in FIG. 10A, all image sensor die 310, which is attached on the substrate 320, is encapsulated by the encapsulant 360 in common. That is, the encapsulant 360 is filling all image sensor die 310 as well as the space between each image sensor die 310. Here, the encapsulant 360 covers the image sensor die 310 located on the outside of the mount holder 340, the substrate 320, and the conductive wires 330. Also, the encapsulant 360 covers parts of the mount holder 340. However, the remaining part of the mount holder 340 is exposed and protruded from the encapsulant 360, so as to receive the external images to the lens 350. Moreover, the encapsulating process may use a molding manner or under fill manner using a dispenser.

As shown in FIG. 10B, each of the image sensor dies 310 attached on the substrate 320 can be encapsulated one by one. That is, an empty space is formed between one image sensor die 310 and a neighboring image sensor die 310 thereof. Here, the encapsulating process may use a molding manner or under fill manner.

Accordingly, by this encapsulating process, the mount holder 340 is not easily separately from the image sensor die 310 and the image sensor die 310, the substrate 320 and the conductive wires 330 can be safely protected from externally mechanical, chemical and electrical impacts. Of course, the electrical conductive wire 330 is completely encapsulated by the encapsulant 360, so that it is not oxidized.

Referring to FIG. 11, a singulation operation among a method for manufacturing an image sensor package according to the present invention is illustrated.

As shown in FIG. 11, next to the encapsulating operation, image sensor packages 300 are singulated from one substrate strip 320′ into individual pieces. That is, the boundary regions between the image sensor packages 300 are separated from each other by means of the diamond blade or punch and so on. Here, where the encapsulant 360 is filling all image sensor die 310 as well as the space between each image sensor die 310, it is preferred that the encapsulant 360 is sawed by the diamond blade along with the substrate 320. Also, in a case that the empty space is formed between the packages (that is, where only substrate 320 is exposed to the encapsulant 360), any one of the diamond blade and punch may be used.

This disclosure provides exemplary embodiments of the present invention. The scope of the present invention is not limited by these exemplary embodiments. Numerous variations, whether explicitly provided for or implied by the specification, such as variations in structure, dimension and type of material and the manufacturing process may be implemented by one who is skilled in the art, in view of this disclosure.

1. An image sensor package comprising:
an image sensor die comprising an approximately planar first surface, an approximately planar second surface opposed to the first surface, an image sensing region formed at an approximately center of the first surface, and at least one bond pad formed at an outside of the image sensing region;
a substrate attached to the second surface of the image sensor die;
at least one conductive wire electrically connecting the bond pad to the substrate;
a mount holder attached on the first surface of the image sensor die between an outside of the image sensing region and the bond pad;
at least one lens for transmitting external images to the image sensing region and located inside the mount holder; and
an encapsulant encapsulating the image sensor die located on an outside of the mount holder and the lens, the substrate, and the at least one conductive wire, wherein the encapsulant comprises an approximately planar first surface approximately perpendicular to a height direction of the mount holder and an approximately planar second surface approximately perpendicular to the first surface of the encapsulant at an end thereof, wherein the substrate comprises an approximately planar first surface bonded to the image sensor die and the electrically conductive wire, an approximately planar second surface opposed to the first surface of the substrate, and a third surface approximately flushed with the second surface of the encapsulant at an edge of the first and second surfaces of the substrate.

2. The image sensor package as claimed in claim 1, wherein a shape of the mount holder is an approximately hollow circular cylinder.

3. The image sensor package as claimed in claim 1, wherein a region of the mount holder is exposed to an outside of the encapsulant.

4. The image sensor package as claimed in claim 1, wherein the at least one lens is exposed to an external atmosphere.

5. The image sensor package as claimed in claim 1, wherein an infrared ray protection coating layer is formed at a surface of the at least one lens.

6. The image sensor package as claimed in claim 1, wherein an infrared ray protection glass is further bonded to an inside of the mount holder.

7. The image sensor package as claimed in claim 1, wherein a barrel having the at least one lens is further coupled to an inside of the mount holder.

8. The image sensor package as claimed in claim 7, wherein an infrared ray protection coating layer is formed at a surface of the at least one lens located at the inside of the barrel.

9. The image sensor package as claimed in claim 7, wherein a plurality of first screw threads is formed at an inside diameter surface of the mount holder and a plurality of second screw threads is formed at an outside diameter surface of the barrel coupled to the first screw threads.

10. The image sensor package as claimed in claim 7, wherein a protrusion protrudes inward from an inside of the mount holder at a lower end of the barrel and an infrared ray protection glass is bonded to the protrusion.

11. The image sensor package as claimed in claim 7, wherein the mount holder comprises a first portion bonded to the image sensor die, a second portion having a diameter larger than that of the first portion thereon, and a plurality of first screw threads formed at an inside diameter surface of the second portion.

12. The image sensor package as claimed in claim 11, wherein the barrel has a plurality of second screw threads formed at an outside diameter surface of the barrel.

13. The image sensor package as claimed in claim 11, wherein the first portion of the mount holder is encapsulated by the encapsulant.

14-19. (canceled)

20. An image sensor assembly comprising:
image sensor dies comprising an approximately planar first surfaces, approximately planar second surfaces opposed to the first surfaces, image sensing regions formed at approximately centers of the first surfaces, and bond pads formed at outsides of the image sensing regions;
a substrate strip comprising a plurality of substrates in a strip, the substrate strip comprising substrates attached to the second surfaces of the image sensor dies;
conductive wires electrically connecting the bond pads to the substrates;
mount holders attached on the first surfaces of the image sensor dies between outsides of the image sensing regions and the bond pads;
lens for transmitting external images to the image sensing regions and located inside the mount holders; and
an encapsulant encapsulating the image sensor dies located on outsides of the mount holders and the lens, the substrates, and the conductive wires, the encapsulant filling spaces between the image sensor dies.

21. An image sensor package comprising:
an image sensor die having an image sensing region and bond pads at one surface thereof;
a mount holder directly attached on the image sensor die;
a substrate, the substrate comprising a first surface, a second surface opposite the first surface, and third surfaces approximately perpendicular to the first and second surfaces, the image sensor die being directly attached on the first surface of the substrate;
conductive wires electrically connecting the bond pads to the substrate; and
an encapsulant encapsulating the image sensor die and the conductive wires, the encapsulant located on an outside of the mount holder, the encapsulant having an approximately planar first surface and approximately planar second surfaces approximately perpendicular to the first surface of the encapsulant, the second surfaces of the encapsulant being flush with the third surfaces of the substrate.

22. The image sensor package as claimed in claim 21, wherein the mount holder is attached between an outside of the image sensing region and the bond pads.

23. The image sensor package as claimed in claim 21, wherein a barrel having at least one lens is further coupled to an inside of the mount holder.

24. The image sensor package as claimed in claim 23, wherein an infrared ray protection coating layer is formed at a surface of the at least one lens.
